(19) United States
(12) Patent Application Publication
(10) Pub. No.: US 2020/0051956 A1
(43) Pub. Date: Feb. 13, 2020

(54) FINE PITCH Z CONNECTIONS FOR FLIP CHIP MEMORY ARCHITECTURES WITH INTERPOSER

(71) Applicant: Intel Corporation, San Clara, CA (US)

(72) Inventors: Omkar KARHADE, Chandler, AZ (US); Nitin DESHPANDE, Chandler, AZ (US); Debendra MALLIK, Chandler, AZ (US)

(21) Appl. No.: 16/100,149

(22) Filed: Aug. 9, 2018

(51) Int. Cl. H01L 25/065; H01L 23/538

(52) U.S. Cl. CPC H01L 25/0657; H01L 23/5386; H01L 2224/48472; H01L 2225/06513; H01L 23/5385

(57) ABSTRACT

A semiconductor package is disclosed. The semiconductor package includes a package substrate, at least one bottom die coupled to the package substrate, at least one interposer coupled to the package substrate and a top die above the at least one bottom die and the at least one interposer and coupled to the at least one bottom die and the at least one interposer. The semiconductor package also includes a plurality of pillars that connect the top die to the package substrate through the at least one interposer.

### TECHNICAL FIELD

Embodiments of the disclosure pertain to connections for flip chip memory architectures, an in particular, to fine pitched z connections for flip chip memory or other die architectures with interposers.

### BACKGROUND

In semiconductor packaging omnidirectional interconnect (ODI) technology requires high density electrical connections between the top die and the substrate. As such, a routing approach is needed which is high in density and low in cost. Mobile products that can benefit from such technology are getting thinner as internet speeds are getting faster. Accordingly, an approach is needed that features thinner modem design and improved thermal characteristics.

Some previous approaches to providing thinner package designs include the reduction of wirebond loop height using reverse bonding and the reduction of mold thickness over wires. However, reducing wirebond loop height using reverse bonding is a slow process that has significant cost impact. Reducing mold thickness above wires can lead to wire exposure failure due to mold flow issues. It is also prone to more wire sweeping or chase pressing on wires.

A previous approach to improving packaging thermal characteristics includes the use of high conductivity mold materials. However, the use of high conductivity mold materials requires the use of materials that have large particles and that require a thick mold cap. Such mold material is difficult to use as underfill and hence can necessitate capillary underfill operations which increase package size in the XY direction and are more expensive.

### BRIEF DESCRIPTION OF THE DRAWINGS

FIG. 1 is an illustration of a cross-section of a semiconductor package designed according to a previous approach.

FIG. 2 is an illustration of a cross-section of a semiconductor package having fine pitched Z connections according to an embodiment.

FIG. 3 is an illustration of a cross-section of a semiconductor package having fine pitched Z connections according to an embodiment.

FIG. 4 is an illustration of diagrams that show example interconnection configurations and associated pitches according to an embodiment.

FIGS. 5A-5C show example interconnects for interposers such as shown in FIGS. 2 and 3 according to an embodiment.

FIG. 6 is a flowchart of a method of forming fine pitched Z connections according to an embodiment.

FIG. 7 is a flowchart of a method of forming fine pitched Z connections according to an embodiment.

FIG. 8 is a schematic of a computer system according to an embodiment.

### DESCRIPTION OF THE EMBODIMENTS

Semiconductor packages having fine pitched Z connections for flip chip memory architectures with interposers are described. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Some previous approaches to providing thinner package designs include the reduction of wirebond loop height using reverse bonding and the reduction of mold thickness over wires. However, reducing wirebond loop height using reverse bonding is a slow process that has significant cost impact. Reducing mold thickness above wires can lead to wire exposure failure due to mold flow issues. It is also prone to more wire sweeping or chase pressing on wires.

A previous approach to improving packaging thermal characteristics includes the use of high conductivity mold materials. However, the use of high conductivity mold materials requires the use of materials that are composed of large particles and that require a thick mold cap. Such mold material is difficult to use as underfill and can necessitate capillary underfill operations which increase package size in the XY direction and are more expensive.

A process and device that addresses the shortcomings of previous approaches is disclosed herein. For example, as part of a disclosed process, a memory is positioned upside down and is provided with direct connections to a package substrate through an interposer that has fine pitched connections. The fine pitched connections provide high density connections, and the exposed backside provides significant Z height reduction and package cooling capacity.

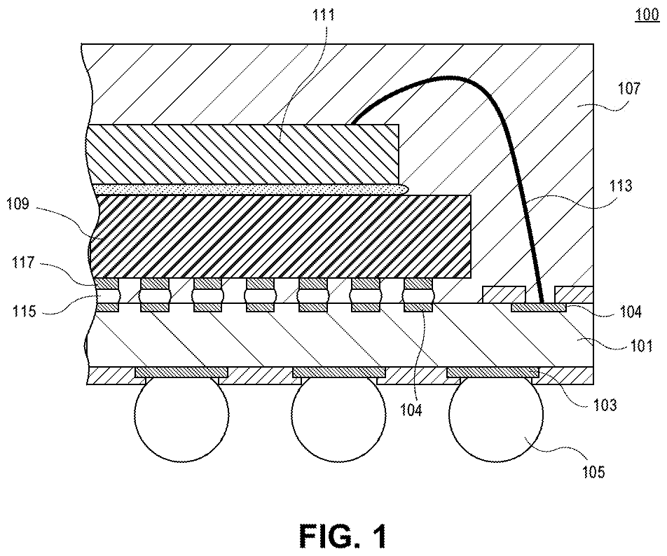

FIG. 1 is an illustration of a cross-section of a semiconductor package 100 of a previous approach. FIG. 1 shows substrate 101, bottom contacts 103, surface contacts 104, solder ball 105, resin 107, baseband die 109, memory die 111, wire bond 113, solder balls 115 and contact 117. In the approach of FIG. 1, the materials used to form substrate 101, bottom contacts 103, surface contacts 104, solder balls 105, mold material 107, baseband die 109, memory die 111, wire bond 113, solder ball 115 and contact 117 are conventional.

Referring to FIG. 1, the package substrate 101 includes bottom contacts 103 and surface contacts 104. The package substrate bottom contacts 103 are coupled to solder ball interconnects 105. The baseband die 109 is coupled to package substrate 101 via baseband die bottom contact 117, solder interconnects 115 and package substrate top surface contacts 104. The memory die 111 is coupled to the top surface of baseband die 109. The memory die 111 is coupled to the package substrate 101 by wire bond 113 and surface contacts 104. The memory die 111 and the baseband die 109 of the package 100 are encapsulated by mold material 107.

Referring to FIG. 1, in order to provide high density connections between the memory die 111 and the package substrate 101, the loop height of the wire bond 113 can be reduced by reverse wire bonding. However, as discussed above, reverse wire bonding techniques can be a slower process than some other conventional wire bonding techniques. The slowness of this process has negative cost impacts. In addition, as discussed above, to provide a thinner package, the mold thickness above the wire bond 113 can be reduced. However, this process can cause wire exposure failure due to mold flow issues.

Mold material 107 can include a high conductivity material selected for improving packaging thermal characteristics. However, as discussed above, the use of high conductivity mold materials require the use of materials that are composed of large particles and that require a thick mold cap. Such mold material is difficult to use as underfill and can necessitate capillary underfill operations which increase package size in the XY direction and are more expensive.

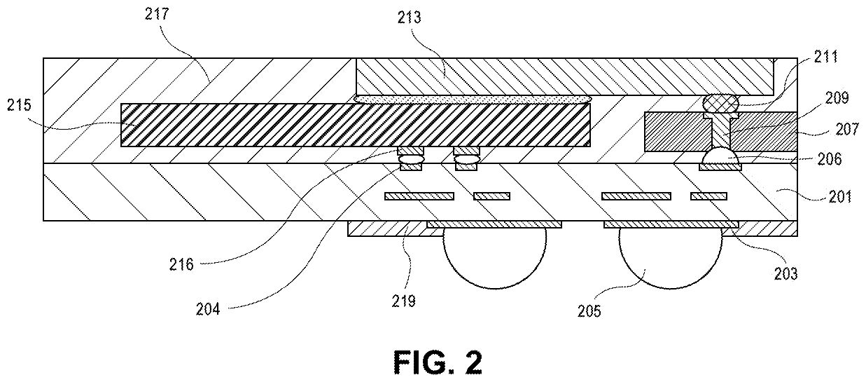

FIG. 2 is an illustration of a cross-section of a semiconductor package 200 with fine pitched Z interconnects according to an embodiment. FIG. 2 shows substrate 201, contacts 203, contacts 204, solder ball 205, solder interconnects 206, interposer 207, via conductor 209, solder interconnect 211, semiconductor die 213, semiconductor die 215, contact 216 and mold 217.

Referring to FIG. 2, the package substrate 201 includes bottom contacts 203 and surface contacts 204. The package substrate bottom contacts 203 are coupled to solder ball interconnects 205. The semiconductor die 215 is coupled to package substrate 201 via baseband die bottom contact 216, solder interconnects 206 and package substrate top surface contacts 204. The semiconductor die 213 is coupled to the top surface of the semiconductor die 215. The semiconductor die 213 is coupled to the package substrate 201 by solder interconnect 211 and via conductor 209. The semiconductor die 213 and the semiconductor die 215 of the semiconductor package 200 are encapsulated by mold 217. However, the backside of the semiconductor die 213 is exposed.

In an embodiment, the package substrate 201 can be formed from organic materials, ceramic materials, silicon or any other suitable material. In other embodiments, the package substrate can be formed from other materials. In an embodiment, the contacts 203, 204 and 216 can be formed from copper. In other embodiments, the contacts 203, 204 and 216 can be formed from other materials. In an embodiment, the via conductor 209 can be formed from copper. In other embodiments, the via conductor can be formed from other materials. In an embodiment, the solder resist 219 can be formed from a polymer. In other embodiments, the solder resist 219 can be formed from other material. In an embodiment, the solder balls 205 can be formed from SnPb. In other embodiments, the solder balls 205 can be formed from other materials. In an embodiment, the solder interconnects 206 and 211 can be formed from SnPb. In other embodiments, the solder interconnects 206 and 211 can be formed from other materials. In an embodiment, the mold 217 can be formed from epoxy resin. In other embodiments, the mold 217 can be formed from other materials.

Referring to FIG. 2, the semiconductor die 213 is mounted upside down on the semiconductor die 215 and is coupled to the package substrate 201 through the interposer 207. In an embodiment, the semiconductor die 213 can include larger pads and/or more solder interconnect 211 than conventional die. In an embodiment, the backside of the semiconductor die 213 is exposed die molded. In an embodiment, this structuring of the package can provide a significant Z height reduction. For example, in the FIG. 2 embodiment, the exposed die molded configuration can provide an approximately 10-20% reduction in Z height for a package 500-1000 um thick. In other embodiments, the exposed die molded design can provide other amounts of reduction. In addition, the exposed die molded design provides efficient package cooling. It should be appreciated that although a single semiconductor die 215 and a single interposer 207 are shown as being attached to the package substrate 201, a plurality of semiconductor die and interposer can be attached to the package substrate 201 in accordance with an embodiment.

In operation, the semiconductor package 200 provides connections to the semiconductor die and dissipates waste heat. In an embodiment, the upside down connection of the semiconductor die 213 to the substrate 201 through interposer 207 provides very high density and direct vertical electrical connections between the top semiconductor die 213 and the substrate 201. These dense connections in addition to the reduced Z height and exposed top semiconductor die 213 backside enables thinly constructed packaging, high routing density and maximal thermal performance that makes the semiconductor package 200 suitable for products having a thin profile that are capable of handling high internet speeds (e.g., thin products such as thin mobile devices).

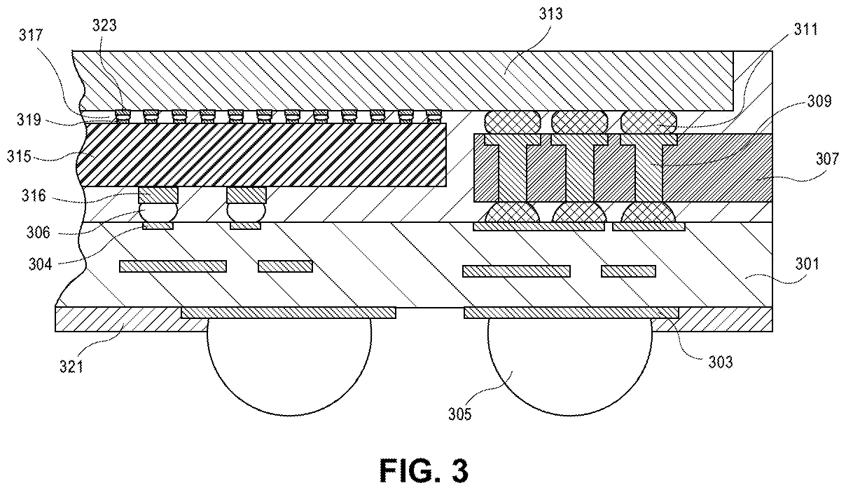

FIG. 3 is an illustration of a cross-section of a semiconductor package 300 according to an embodiment. FIG. 3 shows substrate 301, contact 303, contact 304, solder ball 305, solder interconnects 306, interposer 307, via conductor 309, solder interconnects 311, semiconductor die 313, semiconductor die 315, contact 316, mold 317, contact 319, solder resist 321, and contact 323.

Referring to FIG. 3, the package substrate 301 includes the contacts 303 and the contacts 304. The contacts 303 are coupled to solder ball interconnects 305. The semiconductor die 315 is coupled to the package substrate 301 via the contact 316, the solder interconnects 306 and the contacts 304. The semiconductor die 313 is coupled to the top surface of the semiconductor die 309. The semiconductor die 313 is coupled to the package substrate 301 by the via conductors 309. The semiconductor die 313 and the semiconductor die 315 of the package 300 are encapsulated by mold material 317. In an embodiment, the semiconductor die 313 can be a semiconductor memory die (e.g., LPDDR memory die, etc.). In other embodiments, the semiconductor die 313 can include other types of semiconductor devices. In an embodiment, the semiconductor die 315 can include a mobile device modem die (e.g., digital baseband device, etc.). In other embodiments, semiconductor die 315 can include other types of semiconductor devices.

In an embodiment, the package substrate 301 can be formed from organic or ceramic materials. In other embodiments, the package substrate 301 can be formed from other materials. In an embodiment, the contacts 303, 304, 316, 319 and 323 can be formed from copper. In other embodiments, the contacts 303, 304, 316, 319 and 323 can be formed from other materials. In an embodiment, the solder resist 321 can be formed from a polymer. In other embodiments, the solder resist 321 can be formed from other material. In an embodiment, the solder balls 305 can be formed from SnPb. In other embodiments, solder balls 305 can be formed from other materials. In an embodiment, the solder interconnects 306 can be formed from SnPb. In other embodiments, the solder interconnects 306 can be formed from other materials. In an embodiment, the solder interconnects 311 can be formed from SnPb. In other embodiments, the solder interconnects 311 can be formed from other materials. In an embodiment, the solder interconnects 319 can be formed from SnPb. In other embodiments, the solder interconnects 319 can be formed from other materials. In an embodiment, the mold 317 can be formed from epoxy resin. In other embodiments, the mold 317 can be formed from other materials.

Referring to FIG. 3, the semiconductor die 313 is mounted upside down on the semiconductor die 315 and is coupled to package substrate 301 through interposer 307. In an embodiment, the semiconductor die 313 can be designed with larger pads and/or more solder interconnects 311 than is conventional. In an embodiment, the backside of semiconductor die 313 can be exposed die molded. In an embodiment, this structuring of the package can provide a significant Z height reduction. For example, in an embodiment, using the exposed die molded design can provide an approximately 10-20% reduction in Z height for a package 500-1000 um thick. In other embodiments, the exposed die molded design can provide other amounts of reduction. In addition, the exposed die molded design provides efficient package cooling. It should be appreciated that although a single semiconductor die 315 and a single interposer 307 are shown as being attached to the package substrate 301, a plurality of semiconductor die and interposer can be attached to the package substrate 301 in accordance with an embodiment.

In operation, semiconductor package 300 provides connections to the semiconductor die 313 and the semiconductor die 315 and manages heat. In an embodiment, the upside down connection of the semiconductor die 313 to the substrate 301 through interposer 307 provides very high density direct and vertical electrical connections between the semiconductor die 313 and the substrate 301. These dense connections in addition to the reduced Z height and exposed semiconductor die 313 backside enable thinly constructed packaging, with high routing density and maximal thermal performance that makes semiconductor package 300 suitable for thin mobile products capable of handling high internet speeds.

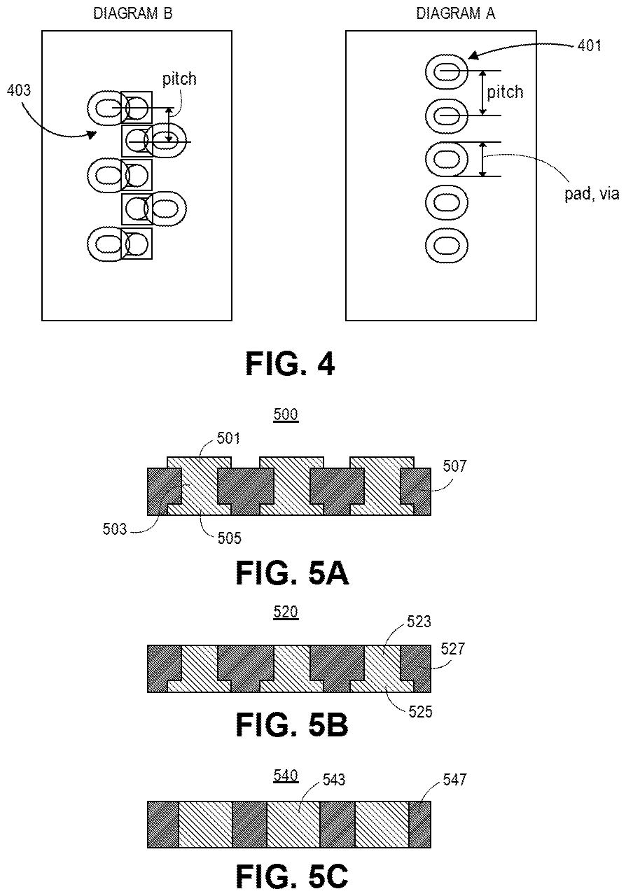

FIG. 4 is an illustration of a diagram that shows example interconnection configurations and associated pitches according to an embodiment. In FIG. 4, diagram A shows an example interconnection configuration of vertically oriented interconnections 401 and diagram B that shows an example interconnection configuration of staggered interconnections 403.

Referring to FIG. 4, diagram A shows vertically oriented interconnections 401 that are positioned in a single line. In an embodiment, the vertically oriented interconnections 401 can be separated by 70 um (e.g., have a 70 um pitch). In other embodiments, the vertically oriented interconnections can be separated by other distances. In an embodiment, the interconnections can include a 25 um via. In other embodiments, the interconnections can include a via that has another width. In an embodiment, the interconnections can include a pad that has a 55 um width. In other embodiments, the interconnections can include a pad that has other widths.

Referring again to FIG. 4, diagram B shows interconnections 403 that have a staggered orientation. In an embodiment, the staggered interconnections 403 can be separated by 55 um (e.g., have a 55 um pitch). In other embodiments, the vertically oriented interconnections can be separated by other distances. In an embodiment, the interconnections can include a 25 um via. In other embodiments, the interconnections can include a via that has another width. In an embodiment, the interconnections can include a pad that has a 55 um width. In other embodiments, the interconnections can include a pad that has other widths.

FIGS. 5A-5C show example interconnects for interposers such as shown in FIGS. 2 and 3 according to an embodiment. FIG. 5A shows a two layer interconnect example. Referring to FIG. 5A, the two layer interconnect 500 includes top pad 501, via conductor or “pillar” 503, and bottom pad 505. The two layer interconnect 500 is formed in interposer 507.

Referring to FIG. 5A, the top pad 501 is formed above the via pillar 503 on the top surface of the interposer 507. The pillar 503 is formed underneath the top pad 501 and above the bottom pad 505. The bottom pad 505 is formed below the via pillar 503 and has a surface that is coplanar with the bottom surface of the interposer 507. In an embodiment, the two layered interconnect design 500 can be formed from copper material. In other embodiments, the two layered interconnect design can be formed from other materials.

In an embodiment, the process flow for fabricating the two layer interconnect design 500 includes forming a first copper layer on a copper foil layer that is formed on the surface of a sacrificial carrier, forming a copper via, forming an overmold, performing a grind back to reveal the via, forming a second copper layer, performing a carrier peel, performing a copper foil etch and performing module singulation. In an embodiment, three masks can be used in the execution of the aforementioned operations in the fabrication of the two layer pillar design 500.

In an embodiment, two layered interconnect 500 provides independent top and bottom pad sizes and copper routing on both the top and the bottom surfaces.

FIG. 5B shows a one and a half substrate layer interconnect example. Referring to FIG. 5A, the one and one half layer interconnect 520 includes via pillar 523, bottom pad 525 and interposer 527. The one and one half interconnect 520 is formed in interposer 527.

Referring to FIG. 5B, the pillar 523 is formed above the bottom pad 525. The bottom pad 525 is formed below the via pillar 523 and has a surface that is coplanar with the bottom surface of the interposer 527. In an embodiment, the one and one half layered interconnect 520 can be formed from copper material. In other embodiments, the one and one half layered interconnect 520 can be formed from other materials.

In an embodiment, the process flow for fabricating the one and one half layer interconnect design 520 includes forming a first copper layer on a copper foil layer that is formed on the surface of a sacrificial carrier, forming a copper via, forming an overmold, performing a grind back to reveal the via, forming a second copper layer, performing a carrier peel, performing a copper foil etch and performing module singulation. In an embodiment, two masks can be used in the execution of the aforementioned operations in the fabrication of the one and one half layer pillar design 520.

In an embodiment, the one and one half layered pillar interconnect 520 is less expensive than the two layered pillar interconnect 500 of FIG. 5A. In an embodiment, the one and one half layered pillar 520 provides copper routing on one surface.

FIG. 5C shows a single layer interconnect example. Referring to FIG. 5C, the single layered interconnect structure 540 includes via pillar 543 and interposer 547. The single layered via pillar interconnect 543 is formed in interposer 547.

In an embodiment, the process flow for fabricating the single layered interconnect design 540 includes forming a first copper layer on a copper foil layer that is formed on the surface of a sacrificial carrier, forming a copper via, forming an overmold, performing a grind back to reveal the via, forming a second copper layer, performing a carrier peel, performing a copper foil etch and performing module singulation. In an embodiment, one mask can be used in the fabrication of the single pillar design 540.

In an embodiment, the one layered pillar interconnect 540 has no misalignment between top and bottom pads, is less expensive than other approaches and has a finer pitch than is provided by other approaches. In an embodiment, via to pad registration is not required.

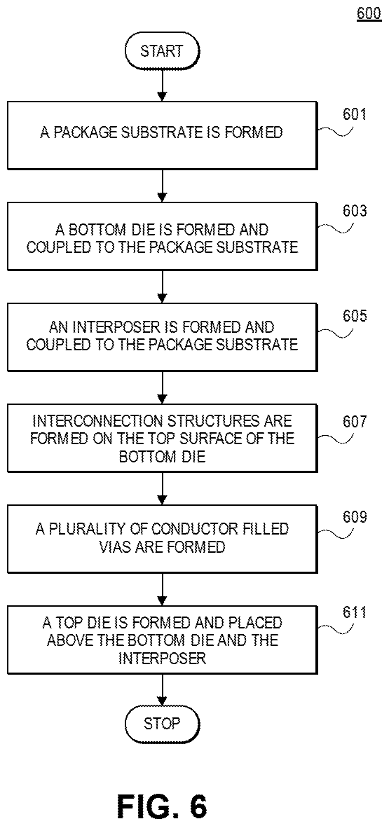

FIG. 6 is a flowchart 600 of a method of forming fine pitched Z connections for flip chip memory architecture according to an embodiment. At 601, a package substrate is formed (e.g., 201 in FIGS. 2 and 301 in FIG. 3). At 603, a bottom die (e.g., 215 in FIGS. 2 and 315 in FIG. 3) is formed and coupled to the package substrate. At 605, an interposer (e.g., 207 in FIGS. 2 and 307 in FIG. 3) is formed and coupled to the package substrate. At 607, interconnection structures are formed on the top surface of the bottom die. At 609, a plurality of conductor filled vias are formed in the interposer. It should be appreciated that in some embodiments, 607 and 609 are performed before the interposer and bottom die respectively are attached to the package substrate. At 611, a top die (e.g., 213 in FIGS. 2 and 313 in FIG. 3) is formed and placed above the bottom die and the interposer and coupled to the bottom die via the interconnection structures and to the package substrate through the conductor filled vias that are formed in the interposer. In another embodiment, interconnection structures may not be formed on the top surface of the bottom die (or between the top die and the bottom die) and the top die can be coupled to the bottom die by an adhesive instead of interconnection structures.

In an embodiment, forming the interconnection structures includes forming microballs. In an embodiment, forming the interposer includes forming protruded bumps on the bottom side of the interposer adjacent the package substrate. In an embodiment, the forming the top die includes plating the die pads of the top die with solder. In an embodiment, the bottom die and the interposer can be underfilled. In an embodiment, the top die can be underfilled.

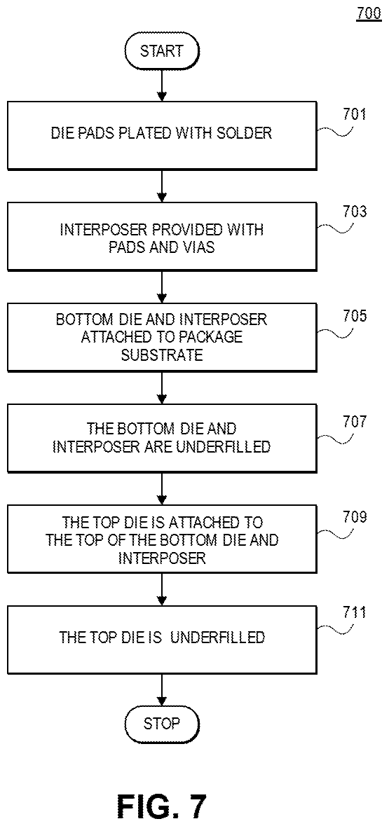

FIG. 7 is a flowchart 700 of an example method of forming fine pitched Z connections for flip chip memory architecture according to an embodiment. At 701, the die pads of a top die (e.g., 213 in FIGS. 2 and 313 in FIG. 3) are plated with solder. At 703, an interposer (e.g., 207 in FIGS. 2 and 307 in FIG. 3) is provided with pads and vias that have predetermined dimensions. In an embodiment, protruded bumps are provided on the bottom side of the interposer that interfaces with the package substrate. In an embodiment, the interposer can be a molded interconnect substrate (MISBGA). In other embodiments, other type interposers can be used. In an embodiment, a package substrate (e.g., 201 in FIGS. 2 and 301 in FIG. 3) can include microballs for connection. In other embodiments, the package substrate can be connected by paste dip. At 705, a bottom die (e.g., 215 in FIGS. 2 and 315 in FIG. 3) and the interposer are attached to the package substrate. At 707, the bottom die and the interposer are underfilled. At 709, the top die is attached to the top surface of the bottom die and the interposer. At 711, the top die is underfilled (if needed). In an embodiment, the package can be exposed die molded or overmolded and ground back to expose the top die backside for cooling.

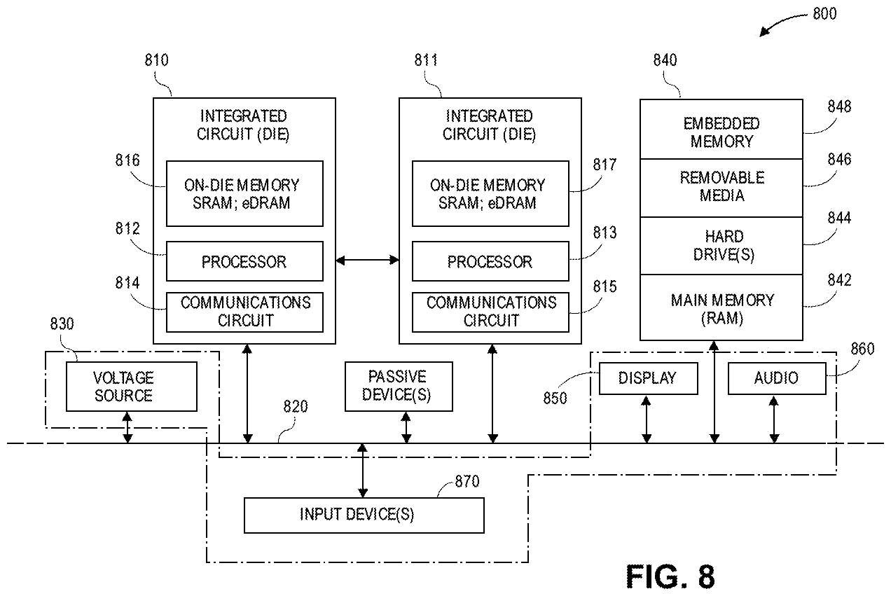

FIG. 8 is a schematic of a computer system 800, in accordance with an embodiment of the present invention. The computer system 800 (also referred to as the electronic system 800) as depicted can embody semiconductor package 200 or semiconductor package 300, according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader. The computer system 800 may be a server system. The computer system 800 may be a supercomputer or high-performance computing system.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes, or is coupled with, semiconductor package 200 or semiconductor package 300, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems, or a communications circuit for servers. In an embodiment, the integrated circuit 810 includes on-die memory 816 such as static random-access memory (SRAM). In an embodiment, the integrated circuit 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 810 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in a die stack, according to an embodiment.

In an embodiment, the electronic system 800 also includes a display device 850, an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a package substrate having semiconductor package 200 or semiconductor package 300, according to any of the several disclosed embodiments and their equivalents, an electronic system, a computer system, one or more methods of fabricating an integrated circuit, and one or more methods of fabricating an electronic assembly that includes the semiconductor package 200 or the semiconductor package 300, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having semiconductor package 200 or semiconductor package 300 embodiments and their equivalents. A foundation substrate may be included, as represented by the dashed line of FIG. 8. Passive devices may also be included, as is also depicted in FIG. 8.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

### Example Embodiment 1

A semiconductor package includes a package substrate, at least one bottom die coupled to the package substrate, at least one interposer coupled to the package substrate, and a top die above the at least one bottom die and the at least one interposer and coupled to the at least one bottom die and the at least one interposer. A plurality of pillars connect the top die to the package substrate through the at least one interposer.

### Example Embodiment 2

The semiconductor package of example embodiment 1, wherein the back side of the top die is exposed.

### Example Embodiment 3

The semiconductor package of example embodiment 1, wherein the plurality of pillars provide vertical connections between the top die and the package substrate.

### Example Embodiment 4

The semiconductor package of example embodiment 1, wherein the plurality of pillars comprise vertical lines of pillars.

### Example Embodiment 5

The semiconductor package of example embodiment 1, wherein the plurality of pillars comprise staggered rows of pillars.

### Example Embodiment 6

The semiconductor package of example embodiment 1, wherein the plurality of pillars is connected to pads.

### Example Embodiment 7

The semiconductor package of example embodiment 1, wherein the top die is coupled to the at least one bottom die by an adhesive.

### Example Embodiment 8

A semiconductor package includes a package substrate,

at least one bottom die coupled to the package substrate, at least one interposer coupled to the package substrate, and a top die above the at least one bottom die and the at least one interposer and communicatively coupled to the at least one bottom die and the at least one interposer. A plurality of pillars connect the top die to the package substrate through the at least one interposer.

### Example Embodiment 9

The semiconductor package example embodiment 8, wherein the back side of the top die is exposed.

### Example Embodiment 10

The semiconductor package of example embodiment 8, wherein the plurality of pillars provide vertical connections between the top die and the package substrate.

### Example Embodiment 11

The semiconductor package of example embodiment 8, wherein the plurality of pillars comprise vertical lines of pillars.

### Example Embodiment 12

The semiconductor package of example embodiment 8, wherein the top die is coupled to the at least one bottom die by electrical interconnections.

### Example Embodiment 13

The semiconductor package of example embodiment 8, wherein the plurality of pillars comprise staggered rows of pillars.

### Example Embodiment 14

The semiconductor package of example embodiment 8, wherein the plurality of pillars is connected to pads.

### Example Embodiment 15

A method includes forming a package substrate, forming at least one bottom die and coupling the at least one bottom die to the package substrate, forming at least one interposer and coupling the at least one interposer to the package substrate, and forming a plurality of conductor filled vias in the interposer. A top die is formed and placed above the at least one bottom die and the at least one interposer and coupled to the at least one bottom die and to the package substrate through the interposer.

### Example Embodiment 16

The example embodiment of claim 15, further including forming interconnection structures for coupling the top die to the at least one bottom die.

### Example Embodiment 17

The example embodiment of claim 15, wherein forming the interposer includes forming protruded bumps on the bottom side of the at least one interposer adjacent the package substrate.

### Example Embodiment 18

The example embodiment of claim 15, wherein the forming the top die includes plating the die pads of the top die with solder.

### Example Embodiment 19

The example embodiment of claim 15, further comprising underfilling the at least one bottom die and the interposer.

### Example Embodiment 20

The example embodiment of claim 15, further comprising underfilling the top die.

What is claimed is:

1. A semiconductor package, comprising:
a package substrate;
at least one bottom die coupled to the package substrate;
at least one interposer coupled to the package substrate;
a top die above the at least one bottom die and the at least one interposer and coupled to the at least one bottom die and the at least one interposer; and
a plurality of pillars that connect the top die to the package substrate through the at least one interposer.

2. The semiconductor package of claim 1, wherein the back side of the top die is exposed.

3. The semiconductor package of claim 1, wherein the plurality of pillars provide vertical connections between the top die and the package substrate.

4. The semiconductor package of claim 1, wherein the plurality of pillars comprise vertical lines of pillars.

5. The semiconductor package of claim 1, wherein the plurality of pillars comprise staggered rows of pillars.

6. The semiconductor package of claim 1, wherein the plurality of pillars is connected to pads.

7. The semiconductor package of claim 1, wherein the top die is coupled to the at least one bottom die by an adhesive.

8. A semiconductor package, comprising:
a package substrate;
at least one bottom die coupled to the package substrate;
at least one interposer coupled to the package substrate;
a top die above the at least one bottom die and the at least one interposer and communicatively coupled to the at least one bottom die and the at least one interposer; and
a plurality of pillars that connect the top die to the package substrate through the interposer.

9. The semiconductor package of claim 8, wherein the back side of the top die is exposed.

10. The semiconductor package of claim 8, wherein the plurality of pillars provide vertical connections between the top die and the package substrate.

11. The semiconductor package of claim 8, wherein the plurality of pillars comprise vertical lines of pillars.

12. The semiconductor package of claim 8, wherein the top die is coupled to the at least one bottom die by electrical interconnections.

13. The semiconductor package of claim 8, wherein the plurality of pillars comprise staggered rows of pillars.

14. The semiconductor package of claim 8, wherein the plurality of pillars is connected to pads.

15. A method, comprising:
forming a package substrate;
forming at least one bottom die and coupling the at least one bottom die to the package substrate;
forming at least one interposer and coupling the at least one interposer to the package substrate;
forming a plurality of conductor filled vias in the at least one interposer; and
forming a top die and placing the top die above the at least one bottom die and the at least one interposer and coupling the top die to the at least one bottom die and coupling the top die to the package substrate through the at least one interposer.

16. The method of claim 15, further including forming interconnection structures for coupling the at least one top die to the at least one bottom die.

17. The method of claim 15, wherein forming the interposer includes forming protruded bumps on the at least one bottom side of the at least one interposer adjacent the package substrate.

18. The method of claim 15, wherein the forming the top die includes plating the die pads of the top die with solder.

19. The method of claim 15, further comprising underfilling the at least one bottom die and the at least one interposer.

20. The method of claim 15, further comprising underfilling the top die.
